(19) United States
(12) Patent Application Publication
(10) Pub. No.: US 2026/0105205 A1
(43) Pub. Date: Apr. 16, 2026

(54) SECURITY BARRIER SYSTEM

(71) Applicant: Meridian Rapid Defense Group, LLC, Pasadena, CA (US)

(72) Inventor: Peter WHITFORD, Pasadena, CA (US)

(21) Appl. No.: 19/354,596

(22) Filed: Oct. 9, 2025

Related U.S. Application Data
(60) Provisional application No. 63/706,167, filed on Oct. 11, 2024.

(51) Int. Cl. G06F 30/13

(52) U.S. Cl. CPC G06F 30/13

(57) ABSTRACT

The present disclosure describes a computer system that generates security barrier configurations for locations. According to an embodiment, a computer system includes one or more memories and one or more processors communicatively coupled to the one or more memories. The one or more processors, individually or collectively, receive a first set of user input indicating an address of an event, retrieve a map showing an area indicated by the address, receive a second set of user input indicating a location in the area to be closed for the event, determine, based on the second set of user input and the map, a size of the location, determine, based on the size, a security barrier configuration for closing the location, and adjust an image of the location by adding an image of the security barrier configuration to the image.

### CROSS-REFERENCE TO RELATED APPLICATIONS

This application claims benefit of co-pending U.S. Prov. Appl. No. 63/706,167 filed October 11, 2024. The aforementioned related patent application is herein incorporated by reference in its entirety.

### TECHNICAL FIELD

Embodiments presented in this disclosure generally relate to a system for configuring security barriers (e.g., portable perimeter defense barriers).

### BACKGROUND

Security barriers may be deployed at event venues to control traffic flows and to secure certain areas of the venues. For example, some configurations of security barriers may block both pedestrian traffic and vehicle traffic, and other configurations may block pedestrian traffic while allowing certain vehicle traffic to pass, and vice versa.

### SUMMARY

The present disclosure describes a computer system that generates security barrier configurations for locations. According to an embodiment, a computer system includes one or more memories and one or more processors communicatively coupled to the one or more memories. The one or more processors, individually or collectively, receive a first set of user input indicating an address of an event, retrieve a map showing an area indicated by the address, receive a second set of user input indicating a location in the area to be closed for the event, determine, based on the second set of user input and the map, a size of the location, determine, based on the size, a security barrier configuration for closing the location, and adjust an image of the location by adding an image of the security barrier configuration to the image.

The one or more processors may, individually or collectively, implement a ruleset indicating security barrier configurations for a plurality of sizes. Determining the security barrier configuration for closing the location may be based on the ruleset.

The one or more processors may, individually or collectively, determine an incursion area for the location based on the second set of user input. Determining the security barrier configuration for closing the location may be based on the incursion area.

The second set of user input may indicate whether the location should allow emergency vehicle access. Determining the security barrier configuration for closing the location may be based on whether the location should allow emergency vehicle access.

The second set of user input may indicate whether the location should allow pedestrian access. Determining the security barrier configuration for closing the location may be based on whether the location should allow pedestrian access.

The one or more processors may, individually or collectively, receive a third set of user input indicating a change to the security barrier configuration and adjust the image of the security barrier configuration based on the change indicated by the third set of user input.

The one or more processors may, individually or collectively, adjust the map by adding a marker to the map at a position in the image indicating the location.

The one or more processors may, individually or collectively, generate a report that includes (i) the map and (ii) the image of the location with the image of the security barrier configuration.

The one or more processors may, individually or collectively, determine a plurality of available security barriers and determine, based on the plurality of available security barriers, a security barrier missing from the plurality of available security barriers to implement the security barrier configuration.

The one or more processors may, individually or collectively, receive, from a security barrier, coordinates indicating a location of the security barrier and verify that the security barrier is deployed at the location according to the security barrier configuration based on the coordinates.

According to another embodiment, a method includes receiving a first set of user input indicating an address of an event, retrieving a map showing an area indicated by the address, receiving a second set of user input indicating a location in the area to be closed for the event, determining, based on the second set of user input and the map, a size of the location, determining, based on the size, a security barrier configuration for closing the location, and adjusting an image of the location by adding an image of the security barrier configuration to the image.

The method may include implementing a ruleset indicating security barrier configurations for a plurality of sizes. Determining the security barrier configuration for closing the location may be based on the ruleset.

The method may include determining an incursion area for the location based on the second set of user input. Determining the security barrier configuration for closing the location may be based on the incursion area.

The second set of user input may indicate whether the location should allow emergency vehicle access. Determining the security barrier configuration for closing the location may be based on whether the location should allow emergency vehicle access.

The second set of user input may indicate whether the location should allow pedestrian access. Determining the security barrier configuration for closing the location may be based on whether the location should allow pedestrian access.

The method may include receiving a third set of user input indicating a change to the security barrier configuration and adjusting the image of the security barrier configuration based on the change indicated by the third set of user input.

The method may include adjusting the map by adding a marker to the map at a position in the image indicating the location.

The method may include generating a report that includes (i) the map and (ii) the image of the location with the image of the security barrier configuration.

The method may include determining a plurality of available security barriers and determining, based on the plurality of available security barriers, a security barrier missing from the plurality of available security barriers to implement the security barrier configuration.

According to another embodiment, a non-transitory computer readable medium stores instructions that, when executed by one or more processors, cause the one or more processors to individually or collectively receive a first set of user input indicating an address of an event, retrieve a map showing an area indicated by the address, receive a second set of user input indicating a location in the area to be closed for the event, determine, based on the second set of user input and the map, a size of the location, determine, based on the size, a security barrier configuration for closing the location, and adjust an image of the location by adding an image of the security barrier configuration to the image.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 illustrates an example system.

FIG. 2A illustrates an example operation performed by the system of FIG. 1.

FIGS. 2B and 2C illustrate example interfaces for the operation shown in FIG. 2A.

FIG. 3A illustrates an example operation performed by the system of FIG. 1.

FIGS. 3B through 3I illustrate example interfaces for the operation shown in FIG. 3A.

FIG. 4A illustrates an example operation performed by the system of FIG. 1.

FIGS. 4B through 4D illustrate example rulesets for the operation shown in FIG. 4A.

FIGS. 4E and 4F illustrate example interfaces for the operation shown in FIG. 4A.

FIGS. 4G through 4I illustrate an example report for the operation shown in FIG. 4A.

FIG. 5 illustrates an example operation performed by the system of FIG. 1.

FIG. 6 is a flowchart of an example method performed by the system of FIG. 1.

FIG. 7 illustrates an example operation performed by the system of FIG. 1.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

Security barriers may be deployed at an event venue to control traffic flows and to secure certain areas of the venue. Generally, several different computer systems at various organizations and departments are used during the planning phase of the event. For example, a computer system for the event organizer may first develop a plan for deploying security barriers at the venue. The plan may indicate the locations where security barriers should be deployed along with the types and number of security barriers at each location. The computer system may then analyze, adjust, and verify the plan or the computer system may communicate the plan to computer systems at other organizations or departments (e.g., police department, fire department, parks and recreation, event coordination, etc.) for analysis, verification, adjustment, and/or approval. Certain technological challenges, however, cause difficulties during the planning phase.

The computer systems involved may select security barriers that are not appropriate for certain locations. For example, the event organizer may select security barriers for a location based on available inventory, aesthetics, or other factors unrelated to properly securing the location. As a result, the plan that the computer system for the event organizer generates may not conform to the rules or regulations that the computer systems for the event organizer and the other organizations and departments follow for properly securing locations. The computer systems may then expend or waste computing resources (e.g., processor and/or memory resources) analyzing, adjusting, or verifying the plan. For example, the computer systems may have difficulty adjusting the plan to satisfy the applicable rules and regulations if the plan deviates too far from the rules and regulations. As a result, the computer systems may be slow when performing the adjustment and verification processes.

The present disclosure describes a computer system that generates security barrier configurations for different locations based on relevant information about the locations. For example, the computer system receives user input indicating the locations at an event venue that are to be closed using security barriers and the types of closures for these locations (e.g., closed to pedestrian traffic and/or vehicular traffic). The computer system may determine the sizes of these locations based on a map of the locations, and then the computer system may determine security barrier configurations that are appropriate for these locations based on the sizes of the locations and the types of closures at the locations. For example, the computer system may implement a ruleset that indicates the appropriate security barrier configurations for different location sizes and types of closures. Using the ruleset, the computer system may determine the appropriate security barrier configurations for closing the locations. The computer system may also retrieve images of the locations and adjust these images by adding images of the determined security barrier configurations to the images of the locations.

In certain embodiments, the computer system provides several technical advantages. For example, the computer system may generate security barrier configurations that comply with rules and regulations, which reduces the computing resources expended to analyze, adjust, and verify a plan that includes the security barrier configurations. The computer system and/or other computer systems may operate much faster when analyzing, adjusting, or verifying the plans generated by the computer system relative to plans generated by existing systems. As another example, the computer system generates images of the security barrier configurations at the locations, which assists in visualizing the security barrier configurations and closures.

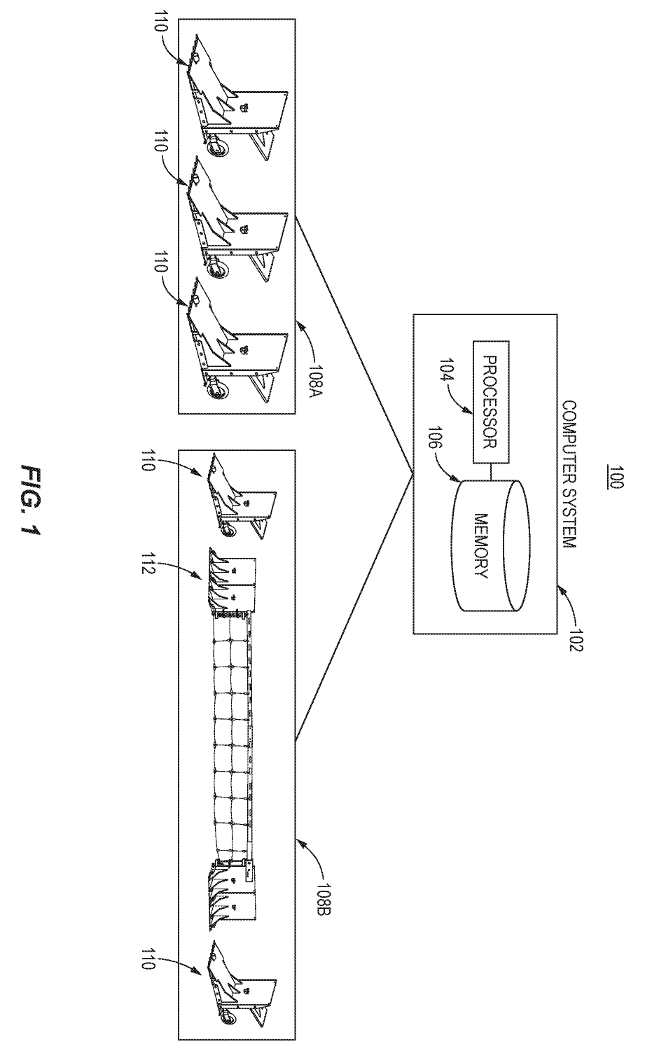

FIG. 1 illustrates an example system 100. As seen in FIG. 1, the system 100 includes a computer system 102. The computer system 102 includes one or more processors 104 and one or more memories 106 that perform the operations and functions of the computer system 102 described herein. Generally, the computer system 102 uses information about an event venue and closure locations at the venue to determine security barrier configurations for implementing the closures.

The processor 104 is any electronic circuitry, including, but not limited to one or a combination of microprocessors, microcontrollers, application specific integrated circuits (ASIC), application specific instruction set processor (ASIP), and/or state machines, that communicatively couples to the memory 106 and controls the operation of the computer system 102. The processor 104 may 8 be-bit, 16-bit, 32-bit, 64-bit or of any other suitable architecture. The processor 104 may include an arithmetic logic unit (ALU) for performing arithmetic and logic operations, processor registers that supply operands to the ALU and store the results of ALU operations, and a control unit that fetches instructions from memory and executes them by directing the coordinated operations of the ALU, registers and other components. The processor 104 may include other hardware that operates software to control and process information. The processor 104 executes software stored on the memory 106 to perform any of the functions described herein. The processor 104 controls the operation and administration of the computer system 102 by processing information (e.g., information received from the users, other computer systems, and/or the memory 106). The processor 104 is not limited to a single processing device and may encompass multiple processing devices contained in the same device or computer or distributed across multiple devices or computers. The processor 104 is considered to perform a set of functions or actions if the multiple processing devices collectively perform the set of functions or actions, even if different processing devices perform different functions or actions in the set.

The memory 106 may store, either permanently or temporarily, data, operational software, or other information for the processor 104. The memory 106 may include any one or a combination of volatile or non-volatile local or remote devices suitable for storing information. For example, the memory 106 may include random access memory (RAM), read only memory (ROM), magnetic storage devices, optical storage devices, or any other suitable information storage device or a combination of these devices. The software represents any suitable set of instructions, logic, or code embodied in a computer-readable storage medium. For example, the software may be embodied in the memory 106, a disk, a CD, or a flash drive. In particular embodiments, the software may include an application executable by the processor 104 to perform one or more of the functions described herein. The memory 106 is not limited to a single memory and may encompass multiple memories contained in the same device or computer or distributed across multiple devices or computers. The memory 106 is considered to store a set of data, operational software, or information if the multiple memories collectively store the set of data, operational software, or information, even if different memories store different portions of the data, operational software, or information in the set.

As explained above, the computer system 102 may receive information from a user about an event venue and locations of the venue to be closed along with the types of closures (e.g., whether the closures should prevent or allow vehicle access, whether the closures should prevent or allow pedestrian access, etc.). The computer system 102 may determine the sizes of these locations (e.g., using a map of the venue), and the computer system 102 may determine security barrier configurations 108 for these locations based on the sizes of the locations and the types of closures. The security barrier configurations 108 may include any number of security barriers and any types of security barriers.

In the example of FIG. 1, the computer system 102 determines security barrier configurations 108A and 108B for different locations at a venue. The security barrier configuration 108A includes multiple barriers 110. The barriers 110 may block both pedestrian traffic and vehicular traffic. The security barrier configuration 108B includes multiple barriers 110 and a beam gate 112. The barriers 110 may block both pedestrian traffic and vehicular traffic. The beam gate 112 may block pedestrian traffic but may be lifted to allow vehicular traffic to pass. As shown in the example of FIG. 1, the computer system 102 may determine security barrier configurations 108 with any number of security barriers and that serve different purposes. The security barrier configurations 108 are not limited to including only barriers 110 or beam gates 112. For example, security barrier configurations may include rapid gates, cables, ramps (e.g., ramps for movement impaired individuals, such as American Disability Act (ADA) compliant ramps), wayfinding frames, etc.

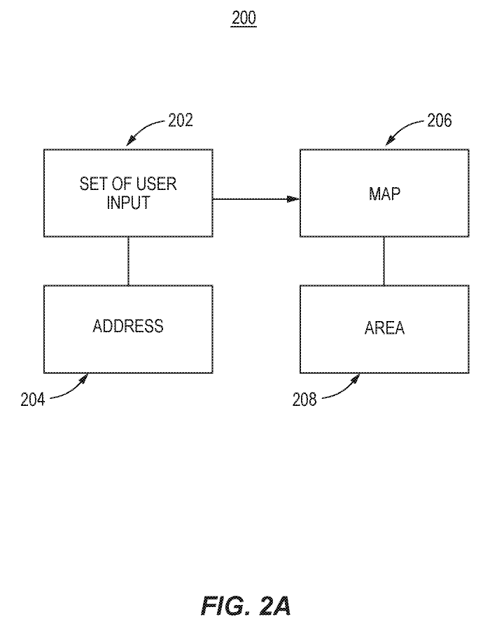

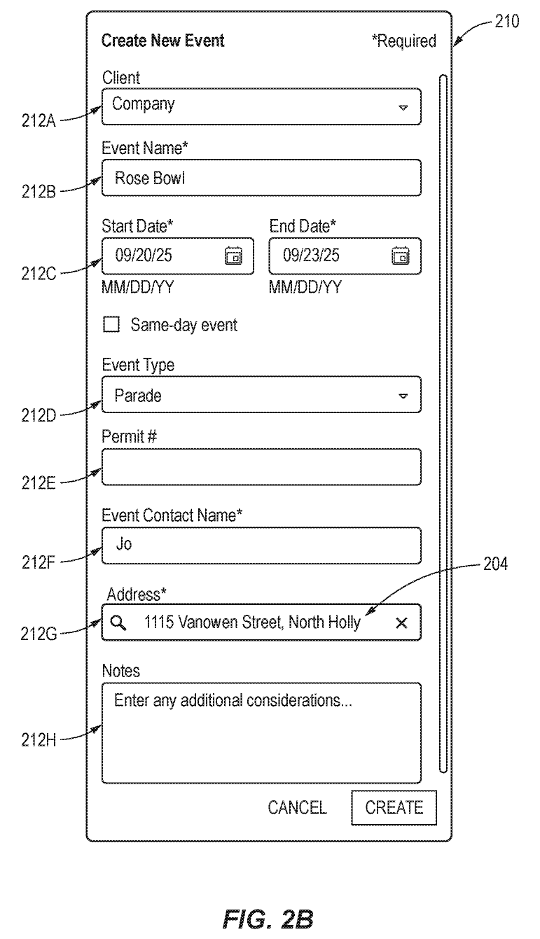

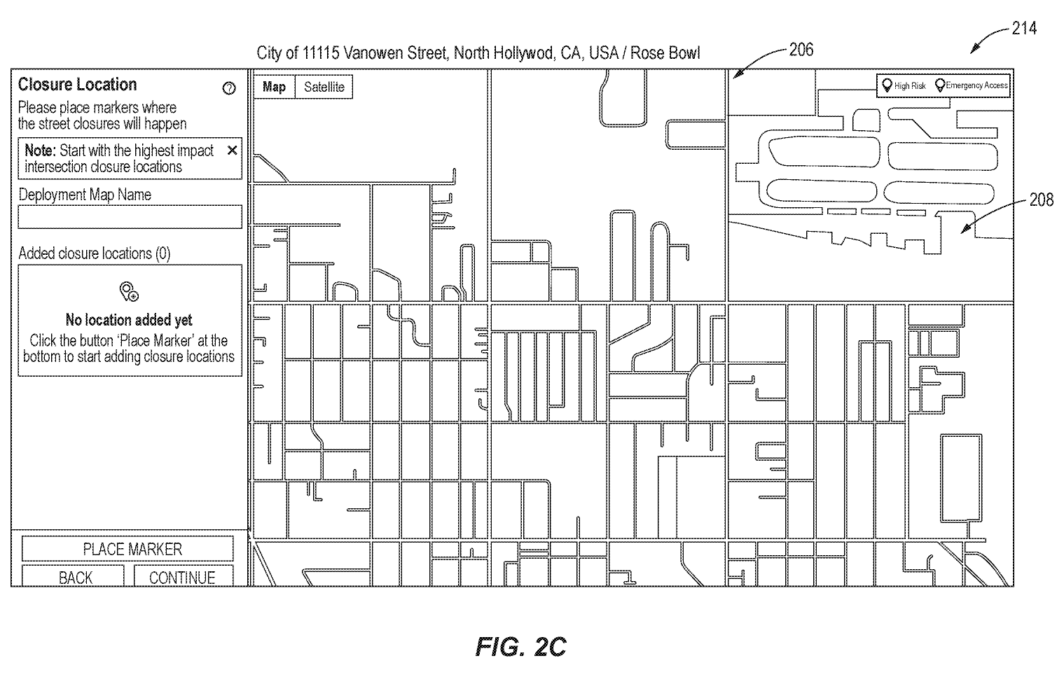

FIG. 2A illustrates an example operation 200 performed by the system 100 of FIG. 1. Generally, a computer system (e.g., the computer system 102 shown in FIG. 1) performs the operation 200. By performing the operation 200, the computer system uses user input to retrieve a map (e.g., a map of an event venue).

The computer system begins by receiving a set 202 of user input. The set 202 of user input may include information about an event venue. For example, the set 202 of user input may include a name for the event, a date for the event, an address 204 for the event, and any other information about the event. A user (e.g., an event organizer) may provide the set 202 of user input using the computer system. By providing the set 202 of user input, the user may indicate a desire for the computer system to determine security barrier configurations for closures at the venue.

The computer system retrieves a map 206 using the address 204. The map 206 may show an area 208 that includes the address 204. The area 208 may include the event venue or that forms part of the event venue. The computer system may use a mapping service to retrieve the map 206. For example, the computer system may communicate the address 204 to the map service, and the map service may communicate the map 206 to the computer system. In some embodiments, the set 202 of user input may include input that manipulates the map 206. For example, the set 202 of user input may pan, zoom, or rotate the map 206. By manipulating the map 206, the computer system may change or focus the area 208 on the event venue.

FIGS. 2B and 2C illustrate example interfaces for the operation shown in FIG. 2A. Generally, the interfaces may be presented on a computer system (e.g., the computer system 102 shown in FIG. 1). A user may interact with the computer system to interact with the interfaces.

FIG. 2B shows an interface 210 presented on the computer system. The interface 210 includes multiple fields 212 through which a user may provide information about an event or event venue. The information provided in the fields 212 may be included in the set 202 of user input shown in FIG. 2A.

In the example of FIG. 2B, the interface 210 includes the fields 212A, 212B, 212C, 212D, 212E, 212F, 212G, and 212H. The field 212A may be used to provide a client name. The field 212B may be used to provide an event name. The field(s) 212C may be used to provide dates for the event. The field 212D may be used to provide an event type. The field 212F may be used to provide a contact name for the event. The field 212G may be used to provide the address 204 for the event. The field 212H may be used to provide notes or a text narrative about the event or concerning the event. A user may use the computer system to provide input in one or more of these fields 212A, 212B, 212C, 212D, 212E, 212F, 212G, and 212H. In the example of FIG. 2B, the user has indicated the address 204 as 1115 Vanowen Street. By providing this information, the user may indicate a desire for the computer system to determine security barrier configurations for closures at the venue with the address 204.

After the computer system receives the information in the interface 210, the computer system may retrieve a map of the event venue using the information in the interface 210. FIG. 2C shows an interface 214 presented on the computer system. Generally, the computer system may present the interface 214 after retrieving the map 206 of the event venue. As seen in FIG. 2C, the interface 214 includes the map 206, which shows the area 208 for the event venue. Using the previous example, the map 206 includes the area 208, which is the section of Vanowen Street indicated by address 204 in the interface 210 shown in FIG. 2B. The user may provide additional input to manipulate (e.g., pan, zoom, rotate, etc.) the map 206 in the interface 214.

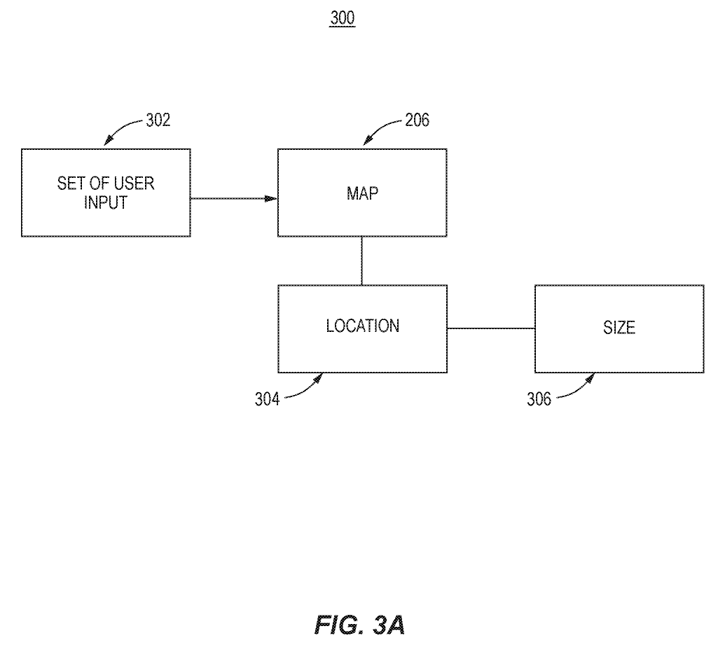

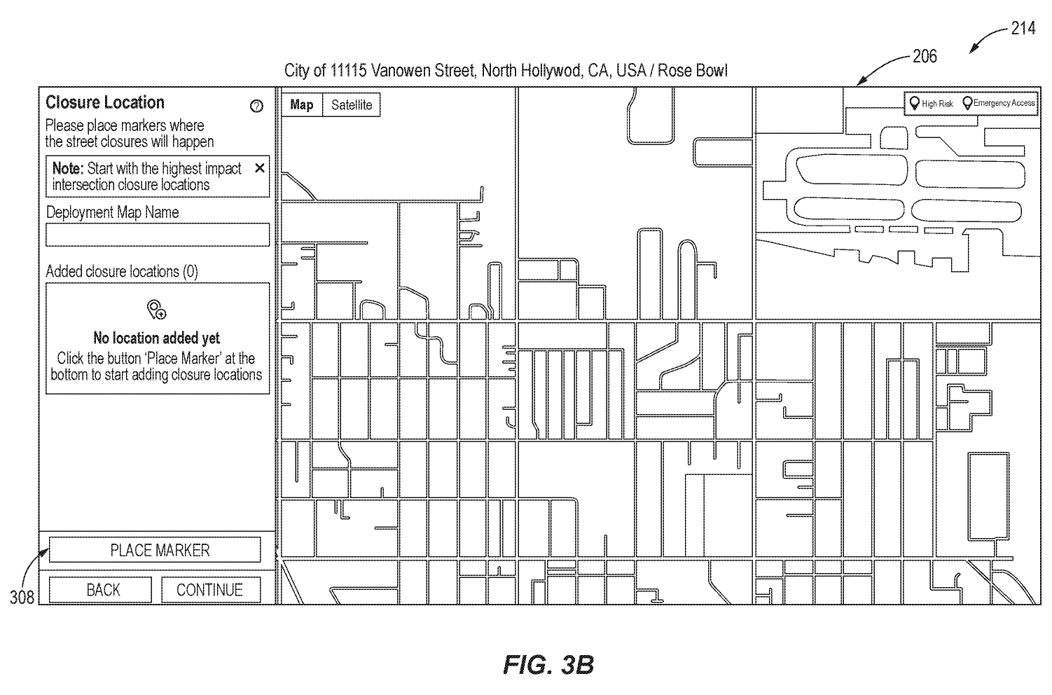

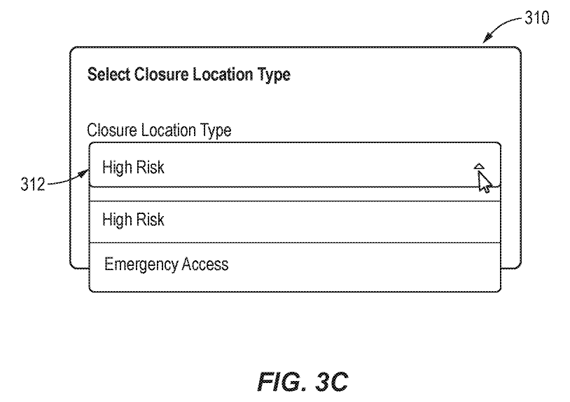

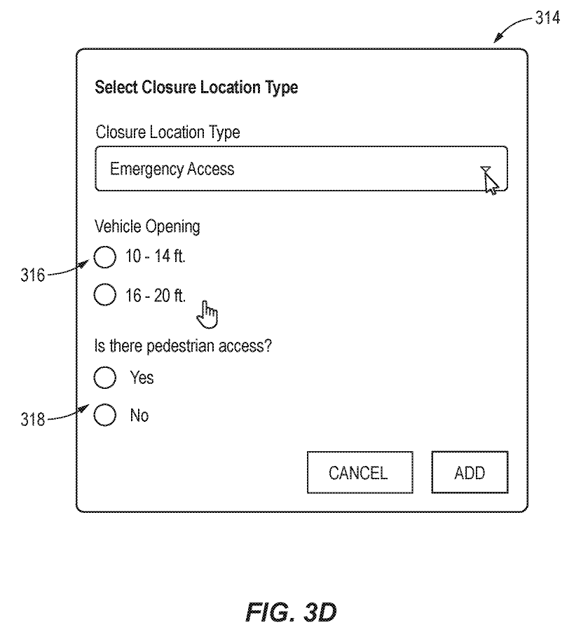

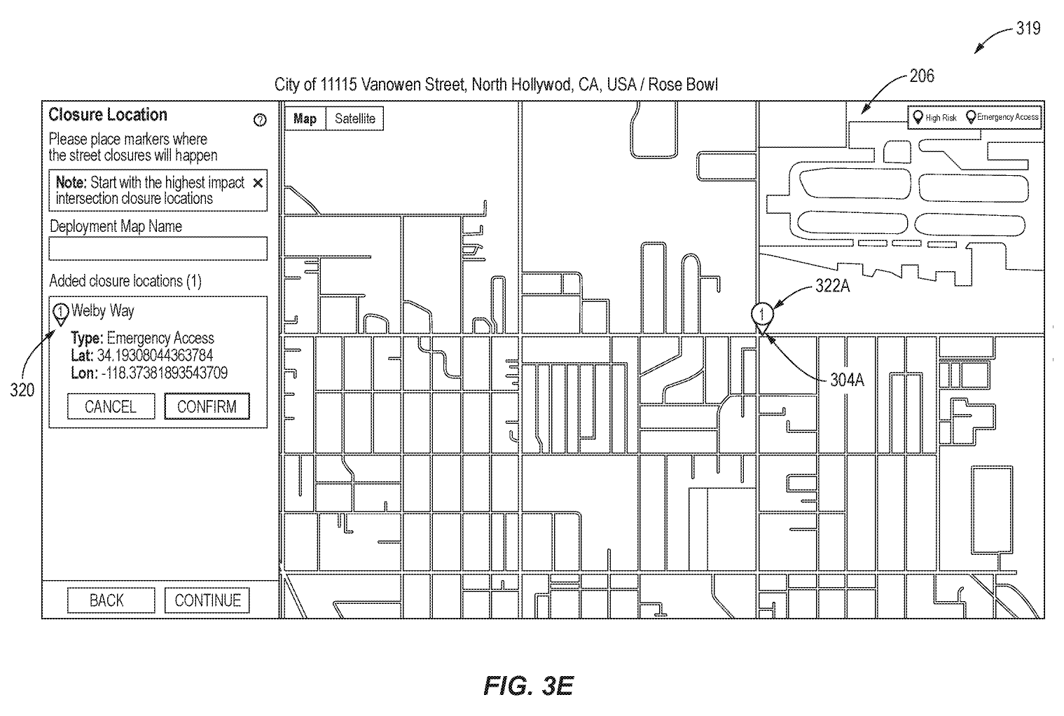

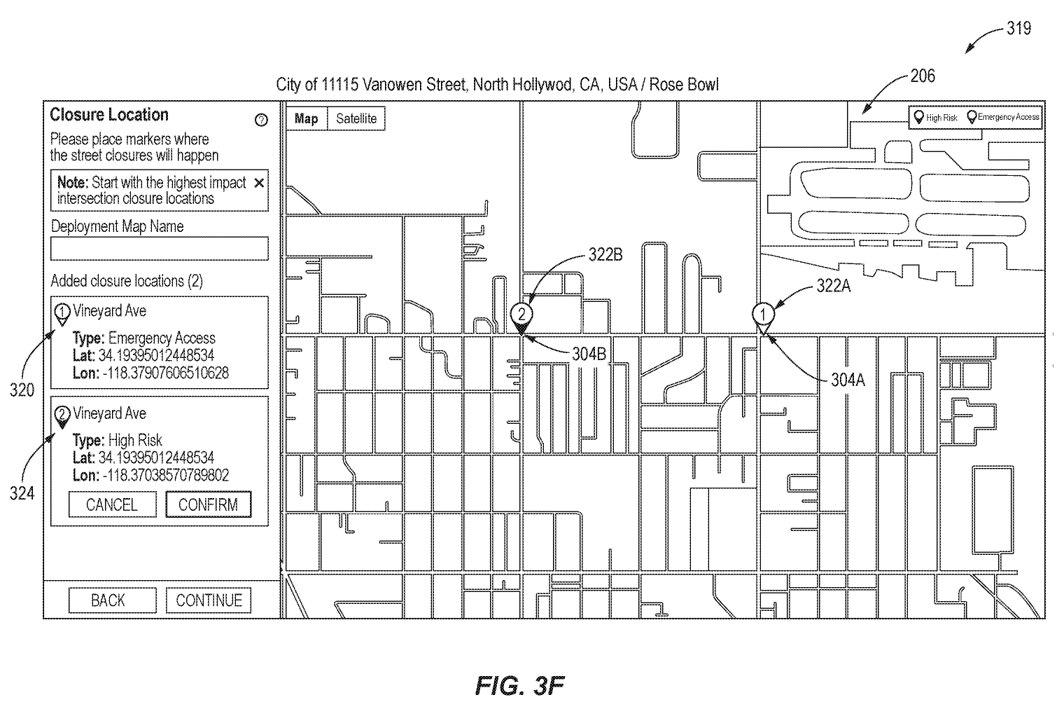

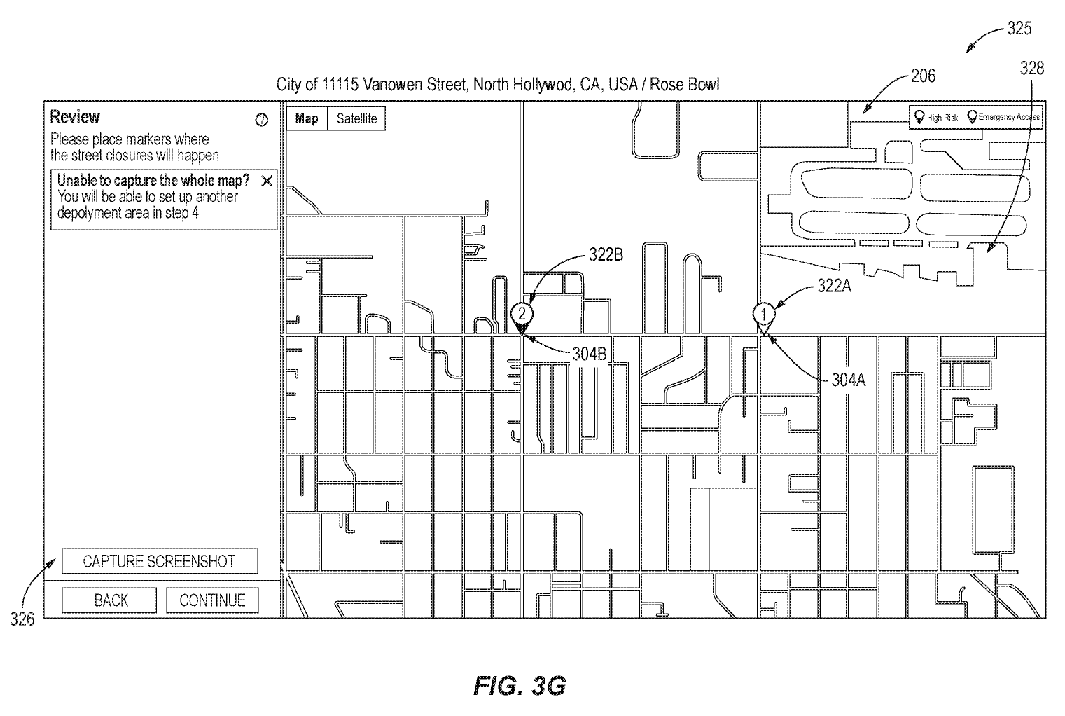

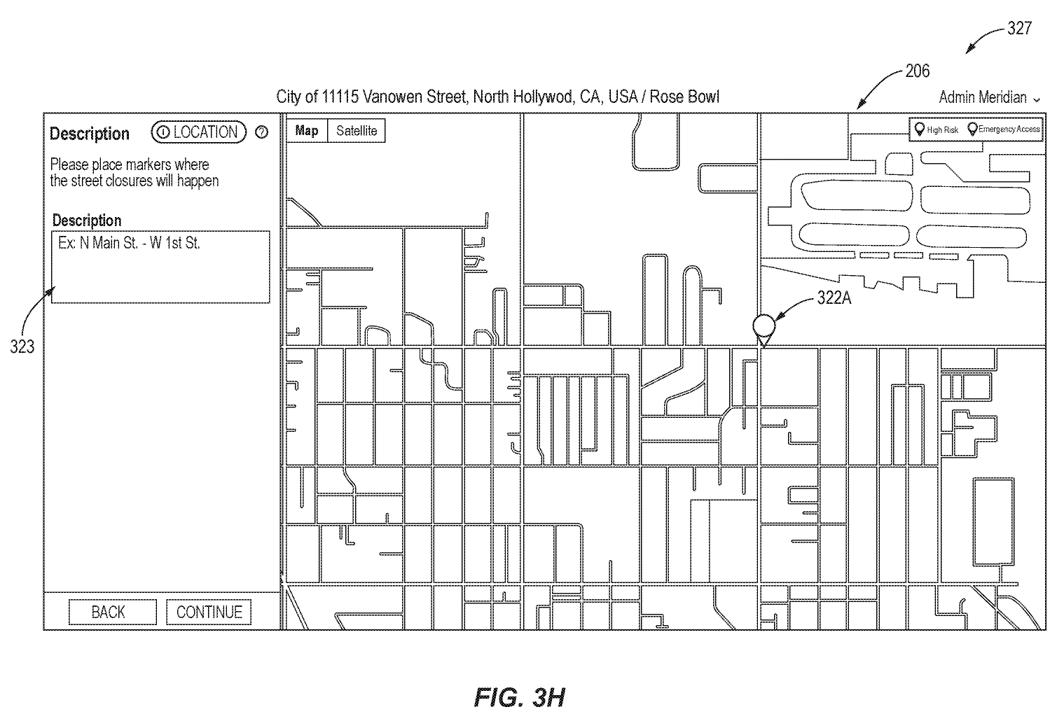

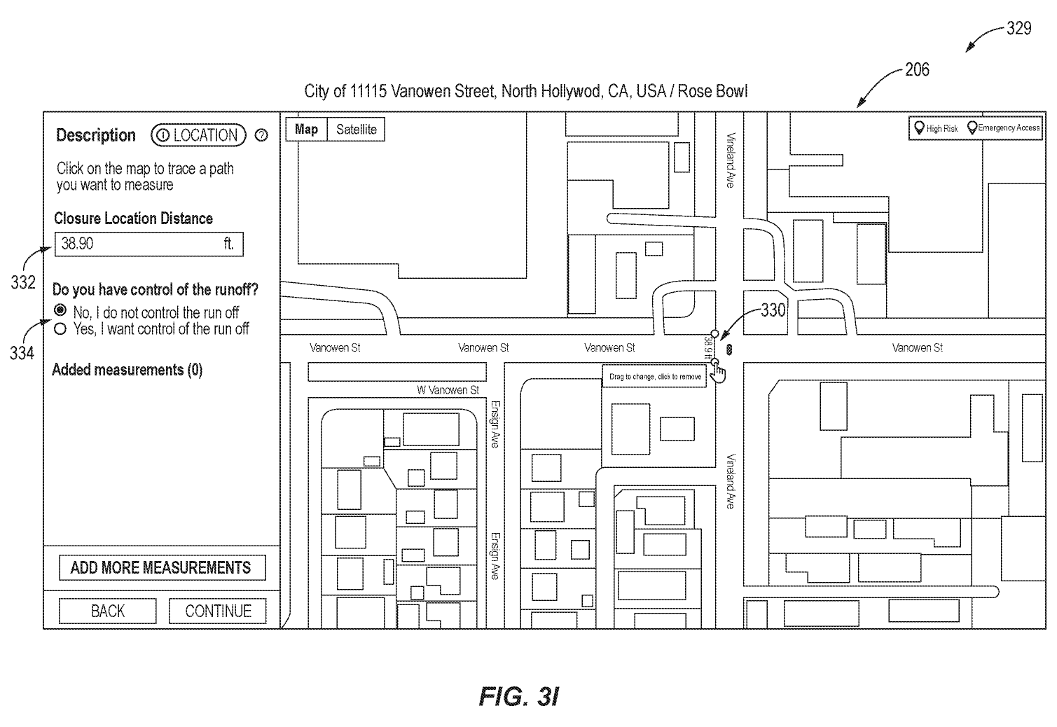

FIG. 3A illustrates an example operation 300 performed by the system of FIG. 1. A computer system (e.g., the computer system 120 shown in FIG. 1) may perform the operation 300. Generally, the operation 300 may be performed after the operation 200 to retrieve the map 206.

The computer system begins by receiving a set 302 of user input. A user may use the computer system to provide the set 302 of user input. The set 302 of user input may include information that indicates a location 304 in the map 206 to be closed. For example, the set 302 of user input may indicate a location 304 as a portion of a road at an intersection at the venue that should be closed. The set 302 of user input may also indicate the type of closer (e.g., closed to pedestrian traffic and/or vehicular traffic).

The computer system uses the set 302 of user input to determine a size 306 of the location 304 that is to be closed. For example, the computer system may use distance metadata in the map 206 to determine a distance represented by a pixel in the displayed map 206, and the computer system may determine a number of pixels used to show the indicated location 304. The computer system then calculates the size 306 of the location 304 by multiplying the number of pixels by the distance represented by a pixel. The computer system may repeat this process to determine the sizes 306 of any number of locations 304 to be closed at the venue.

FIGS. 3B through 3I illustrate example interfaces for the operation 300 shown in FIG. 3A. Generally, the interfaces may be presented on a computer system (e.g., the computer system 102 shown in FIG. 1). A user may interact with the computer system to interact with the interfaces. The information provided by the user using the interfaces shown in FIGS. 3B through 3I may be considered part of the set 302 of user input shown in FIG. 3A.

FIG. 3B shows the interface 214 shown in FIG. 2B. The interface 214 includes a button 308. The user may interact with the button 308 to indicate locations on the map 206 for closures. For example, clicking the button 308 may cause the computer system to allow the user to place markers on the map 206 that indicate the locations of closures.

FIG. 3C shows an interface 310. The computer system may present the interface 310 after the user interacts with the button 308 shown in FIG. 3B. The interface 310 may include a list 312. The user may interact with the list 312 to indicate a type for the closure. In the example of FIG. 3C, the list 312 includes a “High Risk” closure and an “Emergency Access” closure. A high risk closure may indicate that the closure should block both pedestrian traffic and vehicular traffic. An emergency access closure may indicate that the closure should block vehicle traffic generally but allow emergency vehicle traffic.

FIG. 3D shows an interface 314. The computer system may present the interface 314 if the user selects an emergency access closure in the list 312 shown in FIG. 3C. As seen in FIG. 3D, the interface 314 includes buttons (e.g., radio buttons) that a user can use to indicate certain aspects of the emergency access closure. For example, the user may interact with the radio buttons 316 to indicate a width of the vehicle opening for the closure. As another example, the user may interact with the radio buttons 318 to indicate whether the closure should allow pedestrian access. By interacting with the radio buttons 316 and 318, the user provides additional information about the closure to the computer system.

FIG. 3E shows an interface 319. The computer system may present the interface 319 after the user finishes interacting with the interfaces 310 and/or 314 shown in FIGS. 3C and 3D. The interface 319 shows the map 206 like the interface 214 shown in FIG. 3B. The computer system adjusts the map 206 by adding markers 322 to the map 206 at the locations 304. Thus, the markers 322 indicate the closures indicated by the user.

In the example of FIG. 3E, the computer system adds a marker 322A to the map 206 at the location 304A. The marker 322A indicates the emergency access closure selected by the user in the examples of FIGS. 3C and 3D. Additionally, the interface 319 includes a panel 320 that presents information about the closure indicated by the marker 322A. For example, the panel 320 shows a type for the closure indicated by the marker 322A (e.g., emergency access closure) along with coordinates for the location 304A of the closure. The user may interact with the marker 322A on the map 206 to move the marker 322A. As the use moves the marker 322A on the map 206, the information in the panel 320 may update to reflect the changed position of the marker 322A. The user may interact with buttons in the panel 320 to confirm the marker 322A or to remove the marker 322A.

The user may repeat the processes shown in FIGS. 3B through 3E to add additional markers 322 to the map 206 to indicate additional closures at the venue. FIG. 3F shows the interface 319 presented by the computer system after the computer system has added another marker 322B to the map 206. The marker 322B may indicate a high risk closure at another location 304B at the venue. As seen in FIG. 3F, the interface 319 includes another panel 324 for the marker 322B. The panel 324 indicates that the marker 322B is for a high risk closure, and the panel 324 shows the coordinates of the marker 322B and the location 304B. Similar to the marker 322A, the user may use the computer system to move the marker 322B on the map 206, and as the marker 322B moves, the coordinates in the panel 324 update.

After the user has confirmed the markers 322 on the map 206, the computer system may generate an image of the map 206 with the markers 322. FIG. 3G shows an interface 325 presented by the computer system after the markers 322 are confirmed. The interface 325 includes the map 206 and shows the area along with the markers 322. The user may interact with the interface 325 to manipulate the map 206 (e.g., pan, zoom, rotate, etc.). The computer system instructs the user to manipulate the map 206 so that all the markers 322 that the computer system added to the map 206 are visible in the interface 325. The user may then interact with a button 326 in the interface 325 to generate an image 328 of the map 206 with the markers 322 (e.g., by capturing a screenshot).

After the user confirms the markers 322 in the map 206, the computer system may allow the user to provide information about each marker 322. FIG. 3H shows an interface 327 presented by the computer system. The interface 327 includes a box 323 in which the user can provide a description of the markers 322 in the map 206. In the example of FIG. 3H, the user may use the box 323 to input information about the marker 322A in the map 206.

FIG. 3I shows an interface 329 presented by the computer system. The user may interact with the interface 329 to provide information about a closure. In the example of FIG. 3I, the user interacts with the interface 329 to provide information about the closure indicated by the marker 322A shown in FIG. 3H. As seen in FIG. 3I, the user may provide input 330 that shows the boundaries of the closure. The input 330 may include a user-designated start point and a user-designated endpoint that set the boundary of the closure. For example, the user may click-and-drag on the map 206 to indicate the start point and the endpoint, or the user may click on the map 206 to designate the start point and click again on another part of the map 206 to designate the endpoint. In the example of FIG. 3I, the input 330 indicates a closure across the west side of the intersection of Vanowen Street and Vineland Avenue.

The computer system then determines a size of the closure using the input 330. For example, the computer system may use the metadata for the map 206 to determine the size. The map 206 may include a scale that indicates a distance covered by each pixel or set of pixels in the map 206. The computer system may determine the number of pixels used to show the input 330 and multiply that number of pixels by the distance covered by each pixel or set of pixels indicated by the scale to produce the size of the closure. In the example of FIG. 3I, the computer system determines that the size of the closure is 38.90 feet.

The interface 329 includes a box 332 that indicates the size of the closure. The size shown in the box 332 may be updated if the user changes the input 330. For example, if the user changes the start point or endpoint, then the computer system may update the size shown in the box 332 to reflect the new start point and endpoint.

The interface 329 also includes buttons 334 (e.g., radio buttons) that the user uses to indicate whether there is control of the run off. The run off may include the street leading up to the closure. In the example of FIG. 3I, the run off includes Vanowen Street to the east of the intersection. If there is no control of the run off, then vehicles may be driving at regular or fast speeds towards the closure. If there is control of the run off, then vehicles may be driving slowly towards the closure or vehicles may be prevented from approaching the closure altogether. The computer system may use the information about the run off to determine an incursion area for the closure. The incursion area may be an area past the closure that is considered risky or dangerous due to vehicles approaching the closure from the runoff and potentially hitting and moving past the closure. The computer system may determine the size of the incursion area based on whether there is control of the run off and the average or expected speeds of vehicles in the runoff. During the event, the incursion area may be kept clear to reduce risk and danger to participants.

The user may repeat the processes shown in FIGS. 3H and 3I for each marker that the computer system added to the map 206.

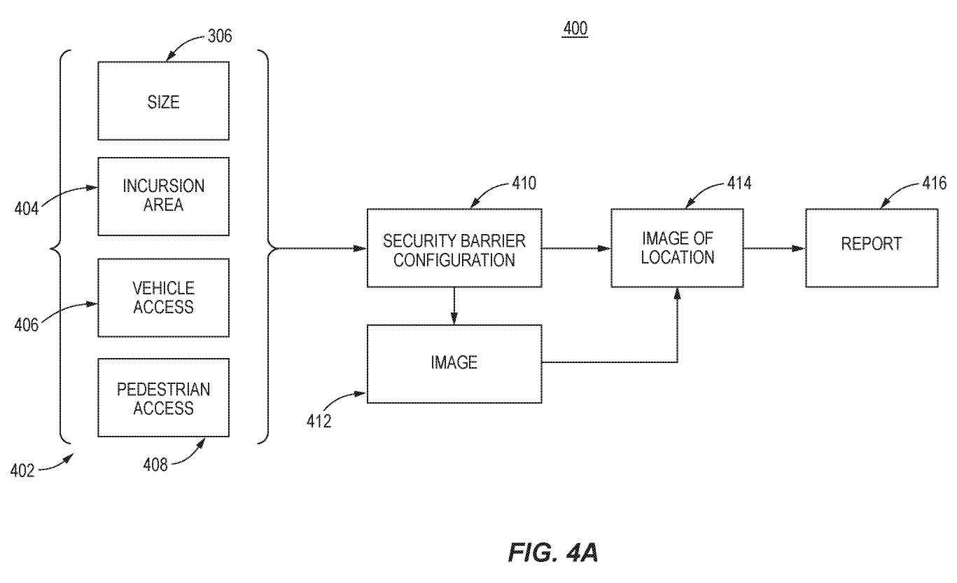

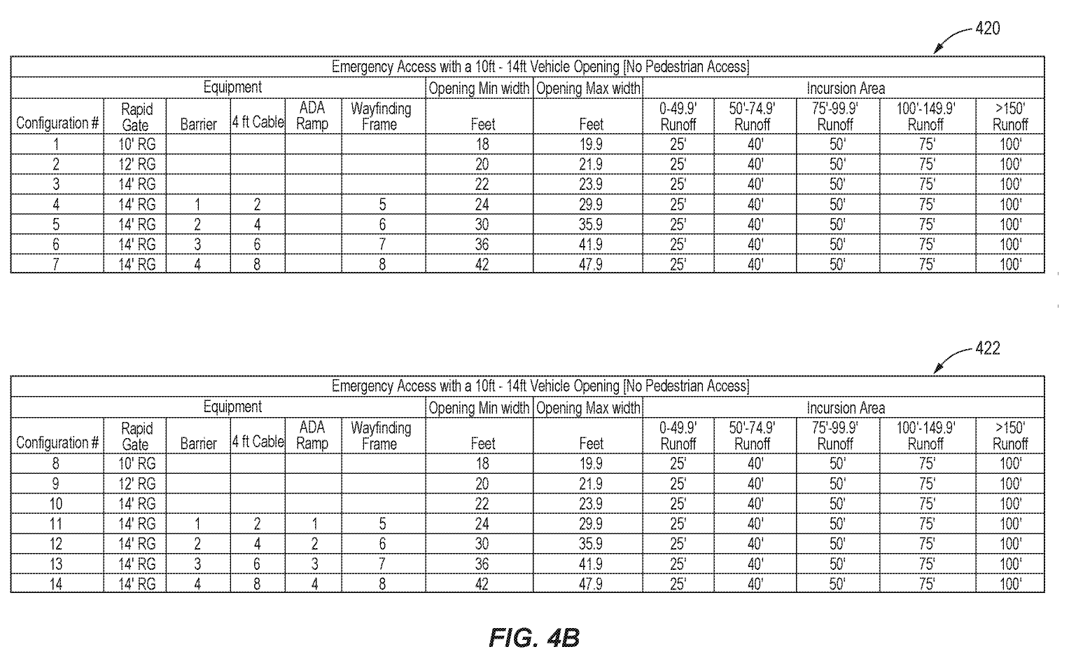

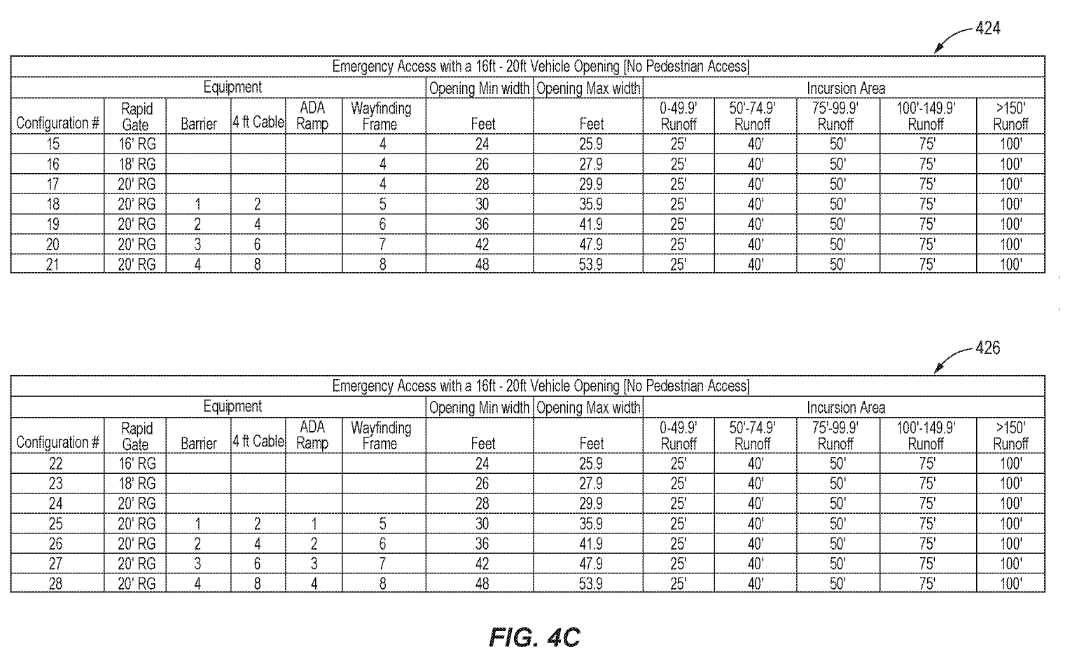

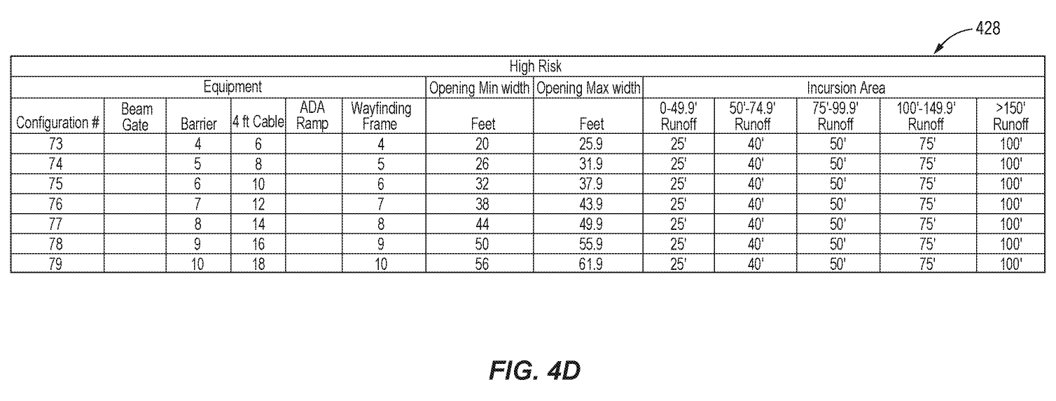

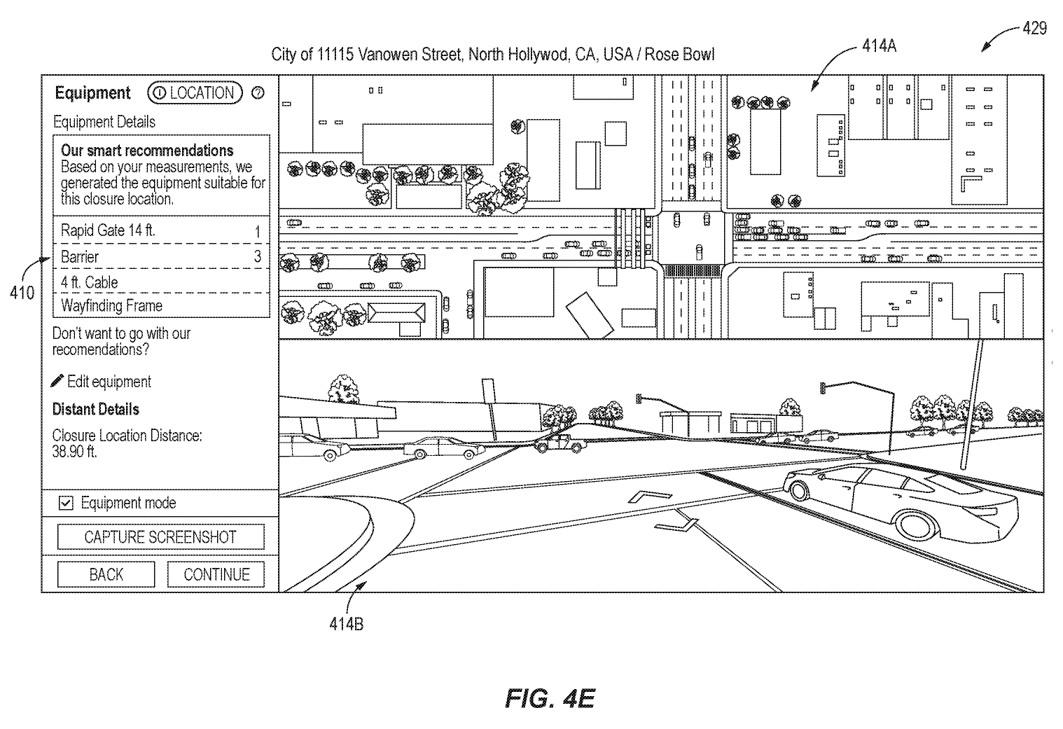

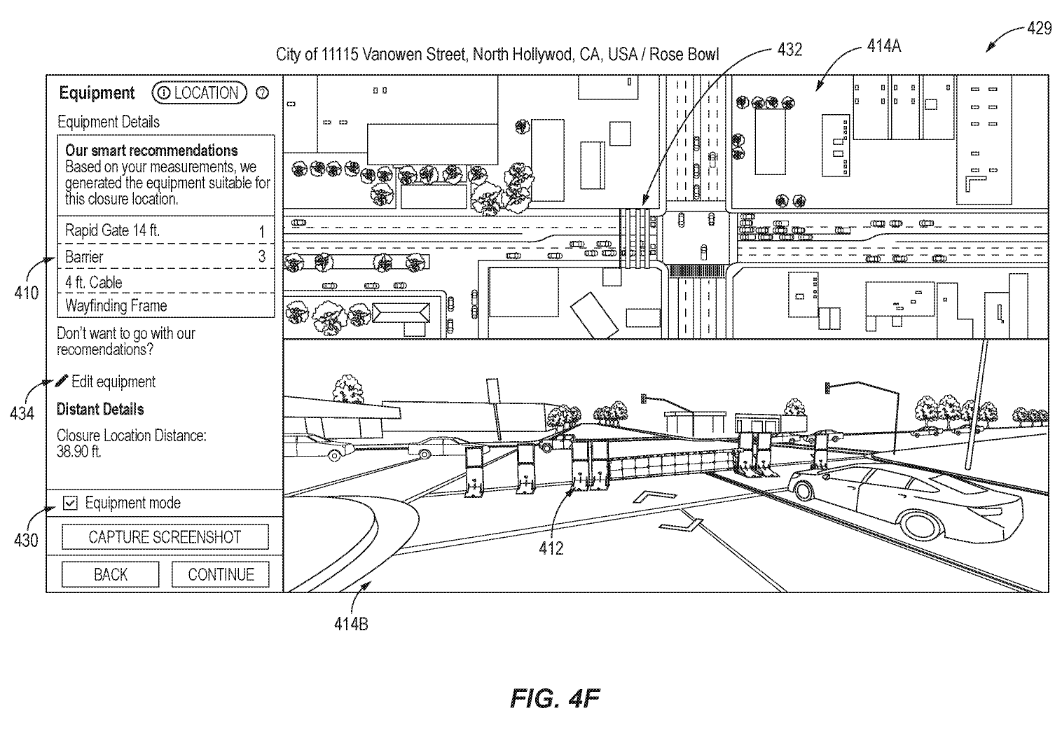

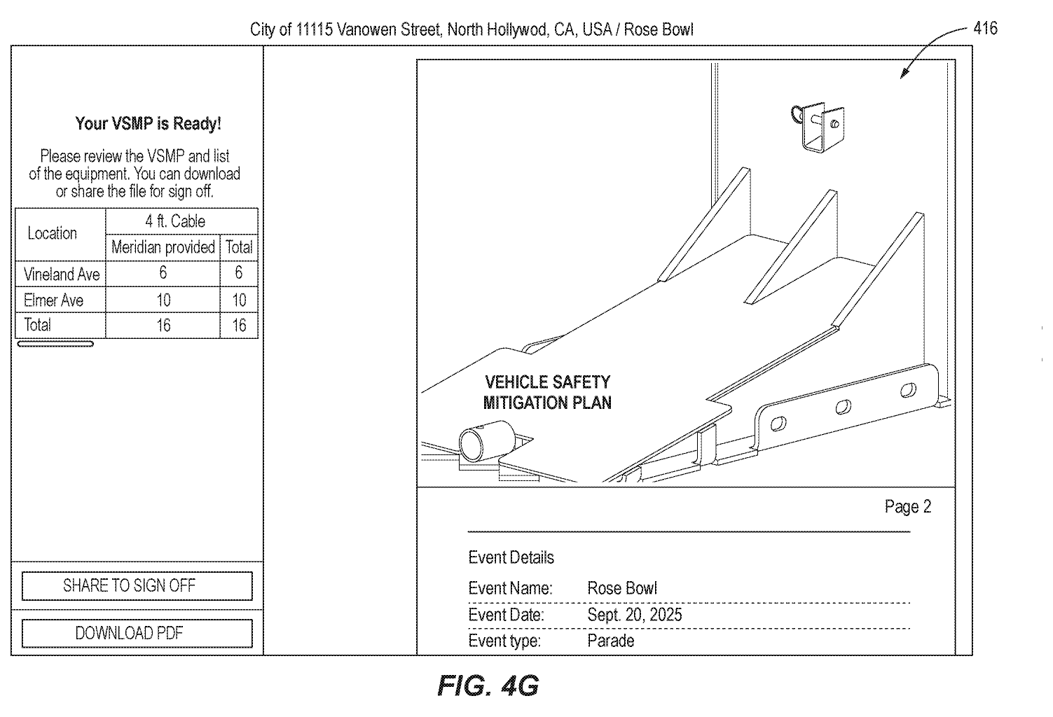

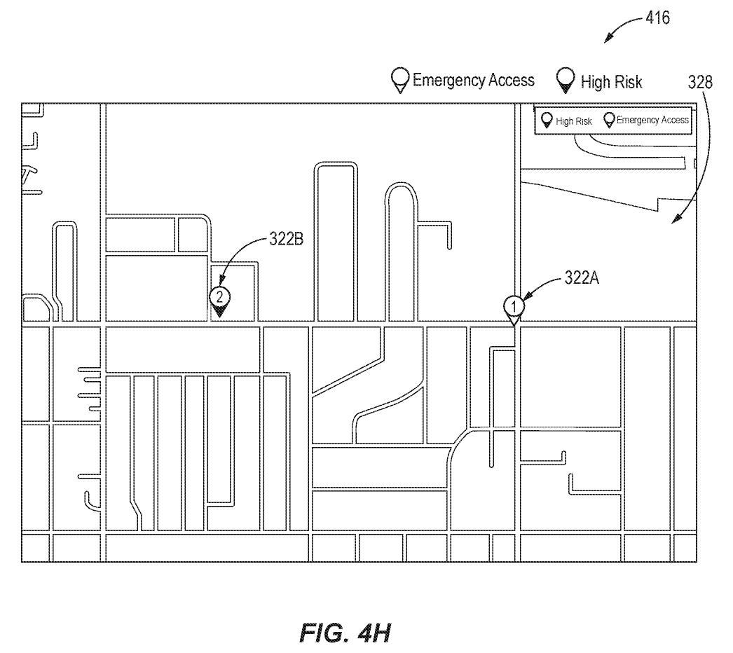

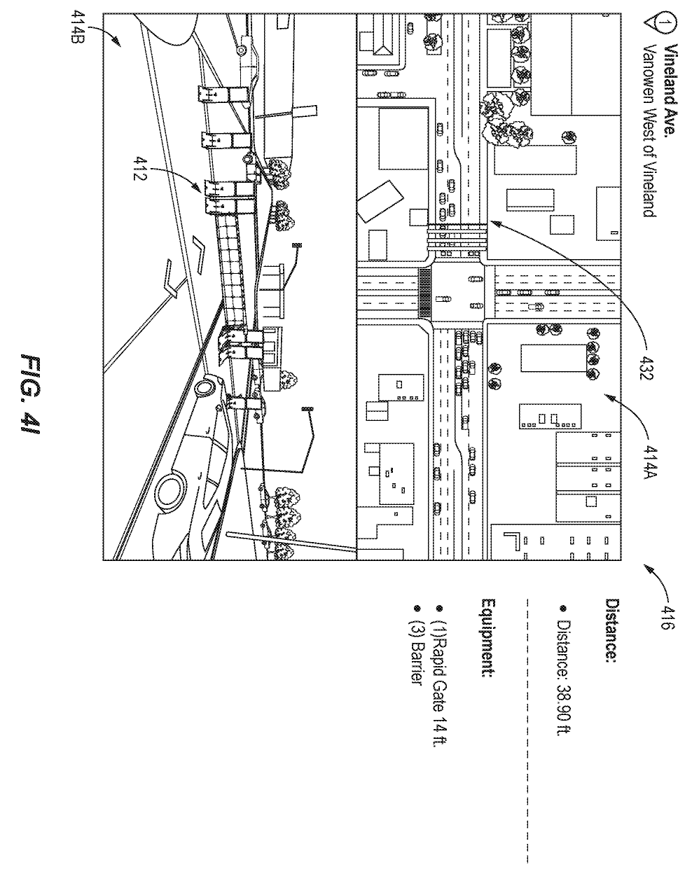

FIG. 4A illustrates an example operation 400 performed by the system of FIG. 1. A computer system (e.g., the computer system 102 shown in FIG. 1) may perform the operation 400 after the size of a closure has been determined. By performing the operation 400, the computer system determines a security barrier configuration for a closure.

The computer system begins with information 402 about a closure. The information 402 may have been previously provided by a user or previously determined by the computer system. The information 402 may include any information about the closure and my not be limited to the types of information shown in FIG. 4A. In the example of FIG. 4A, the information 402 includes the size 306 of the closure, which the computer system may have previously determined. The information 402 also includes information about an incursion area 404 for the closure. For example, the information 402 may indicate a size of the incursion area 404. The information 402 also includes information 406 about whether vehicle access is allowed and information 408 about whether pedestrian access is allowed at the closure.

The computer system uses the information 402 to determine a security barrier configuration 410 for the closure. The security barrier configuration 410 may indicate the types of security barriers to be used (e.g., barriers, rapid gates, beam gates, cables, ramps, wayfinding frames, etc.) for the closure, the number of the types of gates, barriers, and cables, as well as tools and other accessories for installment/removal (e.g., barrier haulers, barrier tow bars, trailers, etc.) to be used. The security barrier configuration 410 may also indicate the arrangement (e.g., the order or sequence) of the security barriers for the closure. The determined security barrier configuration 410 may be appropriate for the securing closure location. For example, the security barrier configuration 410 may include the appropriate number of security barriers, the appropriate types of security barriers, etc. By using the computer system to determine the security barrier configuration 410, the security of the event venue improved relative to when existing systems are used, in certain embodiments. Additionally, the computer system may improve the operation of downstream computer systems in some embodiments. For example, by determining the appropriate security barrier configuration 410 for closure locations, the computer system may reduce the amount of computing resources used to analyze, adjust, and/or verify the security barrier configuration 410, which means the computer systems used to analyze, adjust, and/or verify the security barrier configuration 410 may perform the analysis, adjustment, and/or verification faster relative to when existing systems are used to determine security barrier configurations.

The computer system may use any process to determine the security barrier configuration 410 from the information 402. For example, the computer system may implement a ruleset that indicates what security barrier configurations to use for certain sizes 306, incursion areas 404, and/or traffic access. The ruleset may be implemented in a data structure (e.g., tables, graphs, trees, etc.). The computer system may reference into the data structure using the information 402 to determine which security barrier configuration should be used for the closure. In some embodiments, the computer system may use machine learning models (e.g., neural networks) to determine the security barrier configuration 410. For example, the model may be trained to determine the security barrier configuration 410 from information provided to the model (e.g., the size 306, incursion area 404, traffic access, etc.).

After determining the security barrier configuration 410, the computer system generates or retrieves an image 412 of the security barrier configuration 410. The image 412 may show the security barriers in the security barrier configuration 410 arranged as indicated by the security barrier configuration 410. The computer system may add the image 412 of the security barrier configuration 410 to an image 414 of the location or closure. For example, the computer system may superimpose the image 412 onto the image 414 to show how the security barrier configuration 410 would appear when deployed at the location.

The computer system may generate the image 412 using any process. For example, the computer system may have pre-rendered images of the various security barrier configurations and selected the image 412 from these pre-rendered images. As another example, the computer system may have images of the various security barriers and arranged images of certain security barriers together to form the image 412. The computer system may size the images of the security barrier configurations or the images of the security barriers based on the distances and sizes of the closures previously determined so that the image 412 better fits the perspective shown in the image 414.

In some embodiments, the computer system allows the user to manipulate the image 412 of the security barrier configuration 410 on the image 414. For example, the user may translate, rotate, and/or change the size of the image 412 in the image 414 (e.g., to better fit the scale or perspective shown in the image 414).

The computer system may repeat this process to determine security barrier configurations 410 for every closure location for the event venue. Each closure location may have a different set of information 402, and so the computer system may determine a different security barrier configuration 410 for different closure locations. The computer system may then generate or retrieve images 412 for the security barrier configurations 410 and add those images 412 to images 414 of the different closure locations.

The computer system generates a report 416 for the event venue and the closure locations. The report 416 may include the images 414 of the closure locations with the images 412 of the security barrier configurations 410 added to those images 414. The report 416 may also include an image of the map of the event venue (e.g., the image captured by interacting with the button 326 shown in FIG. 3G). The report 416 may also include information about the event and the venue (e.g., the information provided using the interface 210 shown in FIG. 2B) and information about the closure locations (e.g., information shown in the panels 320 and 324 shown in FIG. 3F and information provided in the boxes 323 and 332 shown in FIGS. 3H and 3I).

The computer system may analyze, adjust, and/or verify the security barrier configurations 410 for the venue, and/or the computer system may communicate the report 416 to other computer systems to analyze, adjust, and/or verify the security barrier configurations 410 for the venue. In certain embodiments, the computer system improves its own operation and/or the operation of other computer systems by determining the security barrier configurations 410 and by including those security barrier configurations 410 in the report 416. For example, the computer system may reduce the amount of computing resources used to analyze, adjust, and/or verify the security barrier configurations 410 because the determined security barrier configurations 410 in the report 416 satisfy rules and regulations governing security barrier deployments. As a result, the computer systems may expend less computing resources and operate more quickly when analyzing, adjusting, and/or verifying the security barrier configurations 410.

As discussed above, the computer system may use any process for determining the security barrier configurations, including using rulesets, data structures, artificial intelligence, etc. FIGS. 4B through 4D illustrate example rulesets for the operation 400 shown in FIG. 4A. Generally, these rulesets are implemented in tables. Each table indicates security barrier configurations for different sizes of closure locations and incursion areas. Different tables may be applied for different types of closures. As discussed above, the computer system may implement the rulesets using any data structure and is not limited to using tables.

FIG. 4B shows a table 420 and a table 422. The table 420 is applicable for emergency access closures with a 10 foot to 14 foot width for the vehicle opening with no pedestrian access. As seen in the table 420, the security barrier configuration for a closure location size between 18 feet and 19.9 feet is a 10 foot rapid gate. For a closure location size between 20 feet and 21.9 feet, the security barrier configuration is a 12 foot rapid gate. For a closure location of 36 feet to 41.9 feet, the security barrier configuration is a 14 foot rapid gate and 3 barriers. Additionally, the configuration may include 6 cables tied between the barriers and/or the rapid gate. Other configurations for different closure location sizes are also shown.

Additionally, the table 420 indicates incursion area sizes for different run off lengths. For example, if the run off is between 0 feet and 49.9 feet, then the incursion area is determined to be 25 feet. If the run off is between 50 feet and 74.9 feet, then the incursion area is determined to be 40 feet. Other incursion area sizes for different run off lengths are shown.

The table 422 is applicable for emergency access closures with a 10 foot to 14 foot width for the vehicle opening with pedestrian access. As seen in the table 422, the security barrier configurations and incursion area sizes are similar to the security barrier configurations and incursion area sizes shown in table 420. The security barrier configurations in the table 422, however, include ADA ramps that provide access for pedestrians with physical impairments (e.g., wheelchairs).

FIG. 4C shows a table 424 and a table 426. The table 424 is applicable for emergency access closures with a 16 foot to 20 foot width for the vehicle opening with no pedestrian access. As seen in the table 424, the security barrier configuration for a closure location size between 24 feet and 25.9 feet is a 16 foot beam gate. For a closure location size between 26 feet and 27.9 feet, the security barrier configuration is an 18 foot beam gate. For a closure location of 42 feet to 47.9 feet, the security barrier configuration is a 20 foot beam gate and 3 barriers. Additionally, the configuration may include 6 cables tied between the barriers and/or the beam gate. Other configurations for different closure location sizes are also shown.

Additionally, the table 424 indicates incursion area sizes for different run off lengths. For example, if the run off is between 0 feet and 49.9 feet, then the incursion area is determined to be 25 feet. If the run off is between 50 feet and 74.9 feet, then the incursion area is determined to be 40 feet. Other incursion area sizes for different run off lengths are shown.

The table 426 is applicable for emergency access closures with a 16 foot to 20 foot width for the vehicle opening with pedestrian access. As seen in the table 426, the security barrier configurations and incursion area sizes are similar to the security barrier configurations and incursion area sizes shown in table 424. The security barrier configurations in the table 426, however, include ADA ramps that provide access for pedestrians with physical impairments (e.g., wheelchairs).

FIG. 4D shows a table 428 that is applicable for high risk closures. As seen in the table 428, the security barrier configuration for a closure location size between 20 feet and 25.9 feet is 4 barriers and 6 cables. For a closure location size between 26 feet and 31.9 feet, the security barrier configuration is 5 barriers and 8 cables. For a closure location of 38 feet to 43.9 feet, the security barrier configuration is 7 barriers and 12 cables. Other configurations for different closure location sizes are also shown.

Additionally, the table 428 indicates incursion area sizes for different run off lengths. For example, if the run off is between 0 feet and 49.9 feet, then the incursion area is determined to be 25 feet. If the run off is between 50 feet and 74.9 feet, then the incursion area is determined to be 40 feet. Other incursion area sizes for different run off lengths are shown.

FIGS. 4E and 4F illustrate example interfaces for the operation shown in FIG. 4A. Generally, the interfaces may be presented on a computer system (e.g., the computer system 102 shown in FIG. 1). A user may interact with the computer system to interact with the interfaces. The interfaces may provide images of closure locations.

FIG. 4E shows an interface 429 presented by the computer system after the closure locations have been confirmed. As seen in FIG. 4E, the interface 429 includes an image 414A and an image 414B. The image 414A shows an aerial view of a closure location (e.g., a satellite view of the closure location). The image 414B shows a street level view of the closure location. Additionally, the interface 429 shows the security barrier configuration 410 that the computer system determined for this closure location. In the example of FIG. 4E, the security barrier configuration 410 includes a 14 foot rapid gate and 3 barriers.

The computer system then adds (e.g., superimposes) images of the incursion area and the security barrier configuration 410 to the images 414A and 414B respectively. FIG. 4F shows the interface 429 after the computer system has added the images. As seen in FIG. 4F, the computer system has added the image 412 of the security barrier configuration 410 to the image 414B, which shows the street level view of the closure location. The image 412 shows the 14 foot rapid gate and 3 barriers arranged linearly along the closure. The rapid gate is positioned between two of the barriers in the security barrier configuration 410. Additionally, the computer system has added the image 432 showing the incursion area to the image 414A, which sows the aerial or satellite view of the closure location. The image 432 shows the size of the incursion area determined for the run off at this closure location. By adding the images 412 and 432 to the images 414A and 414B, the computer system presents a visual representation of how the security barrier configuration 410 will appear at the closure location. Additionally, the computer system shows the size of the incursion area.

The interface 429 also includes a link 434 to edit the security barrier configuration 410. If the user interacts with the link 434, the computer system may allow the user to change the security barriers used in the security barrier configuration 410. If the user makes changes to the security barrier configuration 410 (e.g., selects new security barriers), then the computer system may update the image 412 to show the changed configuration.

The interface 429 also includes a checkbox 430 to show or hide the image 412 and/or the image 432. For example, when the checkbox 430 is checked, the computer system may add the image 412 to the image 414B and/or add the image 432 to the image 414A. When the checkbox 430 is unchecked, the computer system may hide the images 412 and 432 such that the interface 429 resembles what is shown in FIG. 4E.

In some embodiments, the computer system allows the user to manipulate the images 412 and 432 in the interface 429. For example, the computer system may allow the user to translate or rotate the images 412 and 432 in the images 414A and 414B. As another example, the computer system may allow the user to enlarge or shrink the images 412 and 432 in the images 414A and 414B. In this manner, the computer system allows the user to manipulate the images 412 and 432 to better align with the scale and perspectives shown in the images 414A and 414B.

The computer system may repeat the processes shown in FIGS. 4E and 4F for each closure location indicated by the user. For example, for each closure location, the computer system may generate images of the security barrier configuration and incursion area and add these images to images of the closure location.

FIGS. 4G through 4I illustrate an example report 416 for the operation 400 shown in FIG. 4A. As seen in FIG. 4G, the report 416 includes a title page and includes the information about the event and venue (e.g., the information entered in the interface 210 shown in FIG. 2B). As seen in FIG. 4H, the report 416 includes an image 328 of the area for the venue. The image 328 also shows the markers 322A and 322B added by the user to the map to indicate closure locations. As seen in FIG. 4I, the report 416 also includes the images 414A and 414B of a closure location. The image 412 showing the security barrier configuration and the image 432 showing the incursion area are also added to the images 414A and 414B. Additionally, the report 416 shows the size of the closure location and the security barriers used in the security barrier configuration.

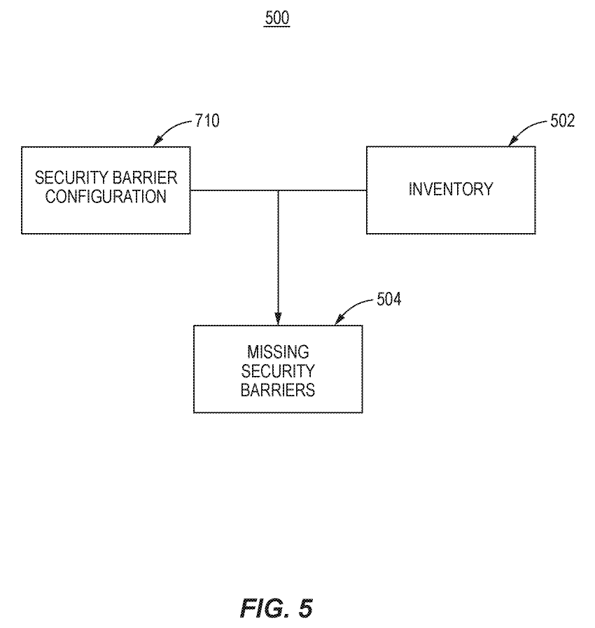

FIG. 5 illustrates an example operation 500 performed by the system of FIG. 1. A computer system (e.g., the computer system 102 shown in FIG. 1) may perform the operation 500. By performing the operation 500, the computer system determines security barriers that are missing to implement a security barrier configuration 410.

The computer system begins by comparing the security barrier configuration 410 to an inventory 502 of available security barriers. The inventory 502 may identify the security barriers that are available for an organization to deploy (e.g., the security barriers that the organization owns or controls). In some instances, the inventory 502 may not include certain security barriers that are indicated by the security barrier configuration 410. The computer system determines these missing security barriers 504 by comparing the security barrier configuration 410 against the inventory 502. After determining the missing security barriers 504, the computer system may present the missing security barriers 504 (e.g., using a message on a display) so that a user can see which security barriers are needed to implement the security barrier configuration 410. The user may then order the security barriers.

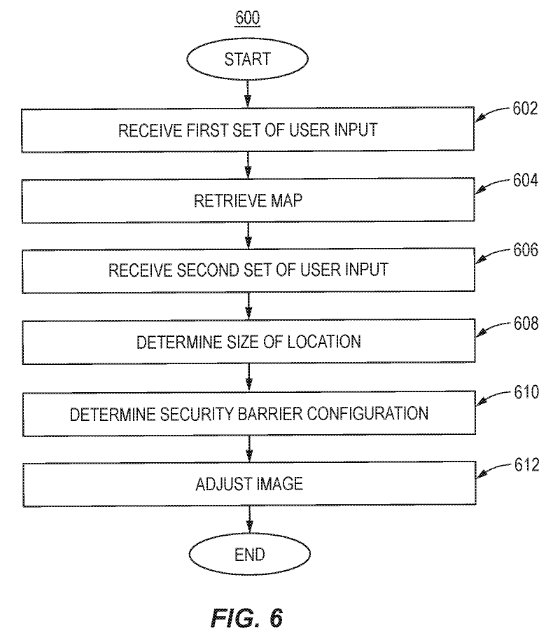

FIG. 6 is a flowchart of an example method 600 performed by the system 100 of FIG. 1. In certain embodiments, a computer system (e.g., the computer system 102 shown in FIG. 1) perform the method 600. By performing the method 600, the computer system determines security barrier configurations for closure locations.

In block 602, the computer system receives a first set of user input. The first set of user input may include information about an event or event venue. For example, the first set of user input may include an event name and a venue address. In block 604, the computer system retrieves a map using the first set of user input. For example, the computer system may communicate the venue address to a map service, and the map service may return a map of the venue address.

In block 606, the computer system receives a second set of user input. The second set of user input may include information about closure locations at the venue and the types of closures. For example, the second set of user input may indicate high risk closures and emergency access closures. The second set of user input may also indicate other information about the closures such as the width of vehicle openings and whether pedestrian access is allowed. The second set of user input may also include the positions (e.g., coordinates) of the closure locations. The second set of user input may further indicate the boundaries of the closure locations (e.g., start points and endpoints).

In block 608, the computer system determines the size of a closure location using the second set of user input. For example, the computer system may determine a number of pixels between the start point and endpoint of the closure location shown in the map. The computer system may then determine (e.g., using the map metadata) the distance covered by each pixel. Using this information, the computer system may then determine the distance covered by the closure location.

In block 610, the computer system determines a security barrier configuration using the size of the closure location. For example, the computer system may implement a ruleset that indicates different security barrier configurations for different sizes of closure locations. Referencing into this ruleset with the size of the closure location may produce the security barrier configuration for the closure location. In block 612, the computer system adjusts an image of the closure location by adding an image of the security barrier configuration to the image of the closure location. For example, the computer system may superimpose the image of the security barrier configuration onto the image of the closure location. In this manner, the computer system generates a visual representation of the security barrier configuration at the closure location.

In some implementations, the rulesets discussed in this application may be determined through tests (e.g., crash tests) involving various security gates. For example, different vehicles may be crashed into different security gate configuration to determine how the gates should be spaced and deployed.

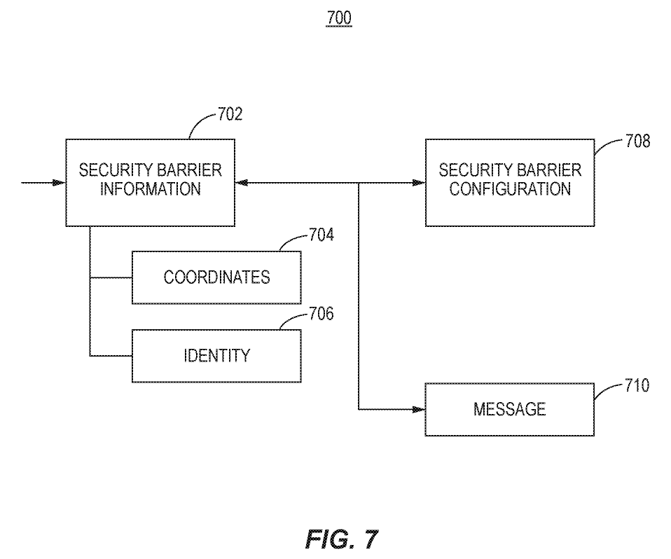

FIG. 7 illustrates an example operation 700 performed by the system 100 of FIG. 1. Generally, a computer system (e.g., the computer system 102 shown in FIG. 1) performs the operation 700. By performing the operation 700, the computer system verifies a security barrier configuration.

The computer system begins by receiving security barrier information 702. The security barrier information 702 may include information about a deployed security barrier. In the example of FIG. 7, the security barrier information 702 indicates coordinates 704 of the security barrier and an identity 706 of the security barrier. In some embodiments, the security barrier includes a global positioning system (GPS) receiver that receives or determines the coordinates 704 for the geolocation of the security barrier. The security barrier may also include a transmitter that transmits the coordinates 704 along with other information about the security barrier (e.g., the identity 706) to the computer system.

The computer system compares the security barrier information 702 to a security barrier configuration 708 to verify that the security barrier is deployed correctly. For example, the computer system may determine whether the coordinates 704 indicate that the security barrier is deployed at a location indicated by the security barrier configuration 708. The computer system may generate and transmit a message 710 indicating whether the security barrier is deployed correctly. For example, the computer system may display the message 710 to indicate to an operator of the computer system that the security barrier is deployed correctly or incorrectly. Additionally or alternatively, the computer system may indicate in the security barrier configuration 708 or in a map that the security barrier is deployed correctly or incorrectly (e.g., by using different colored symbols). Additionally or alternatively, the computer system may transmit the message 710 to the security barrier, and the security barrier may provide a visual or audio indication that the security barrier is deployed correctly or incorrectly. For example, the security barrier may display a message, generate audio, or turn on or off a light to indicate that the security barrier is deployed correctly or incorrectly.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

As will be appreciated by one skilled in the art, the embodiments disclosed herein may be embodied as a system, method or computer program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, embodiments may take the form of a computer program product embodied in one or more computer readable medium(s) having computer readable program code embodied thereon.

Program code embodied on a computer readable medium may be transmitted using any appropriate medium, including but not limited to wireless, wireline, optical fiber cable, RF, etc., or any suitable combination of the foregoing.

Computer program code for carrying out operations for embodiments of the present disclosure may be written in any combination of one or more programming languages, including an object oriented programming language such as Java, Smalltalk, C++ or the like and conventional procedural programming languages, such as the "C" programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described herein with reference to flowchart illustrations and/or block diagrams of methods, apparatuses (systems), and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the block(s) of the flowchart illustrations and/or block diagrams.

These computer program instructions may also be stored in a computer readable medium that can direct a computer, other programmable data processing apparatus, or other device to function in a particular manner, such that the instructions stored in the computer readable medium produce an article of manufacture including instructions which implement the function/act specified in the block(s) of the flowchart illustrations and/or block diagrams.

The computer program instructions may also be loaded onto a computer, other programmable data processing apparatus, or other device to cause a series of operational steps to be performed on the computer, other programmable apparatus or other device to produce a computer implemented process such that the instructions which execute on the computer, other programmable data processing apparatus, or other device provide processes for implementing the functions/acts specified in the block(s) of the flowchart illustrations and/or block diagrams.

The flowchart illustrations and block diagrams in the Figures illustrate the architecture, functionality, and operation of possible implementations of systems, methods, and computer program products according to various embodiments. In this regard, each block in the flowchart illustrations or block diagrams may represent a module, segment, or portion of code, which comprises one or more executable instructions for implementing the specified logical function(s). It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications may be made without departing from the spirit and scope of the present disclosure. Accordingly, it is not intended that the present disclosure be limited thereby. Likewise, the term "comprising" is considered synonymous with the term "including" for purposes of United States law. Likewise, whenever a composition, an element, or a group of elements is preceded with the transitional phrase "comprising", it is understood that the same composition or group of elements with transitional phrases "consisting essentially of", "consisting of", "selected from the group of consisting of", or "is" preceding the recitation of the composition, element, or elements and vice versa, are contemplated. As used herein, the term "about" refers to a +/-10% variation from the nominal value. It is to be understood that such a variation may be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

In view of the foregoing, the scope of the present disclosure is determined by the claims that follow.

We claim:

1. A computer system comprising:
one or more memories; and
one or more processors communicatively coupled to the one or more memories, the one or more processors configured to, individually or collectively:
receive a first set of user input indicating an address of an event;
retrieve a map showing an area indicated by the address;
receive a second set of user input indicating a location in the area to be closed for the event;
determine, based on the second set of user input and the map, a size of the location;
determine, based on the size, a security barrier configuration for closing the location; and
adjust an image of the location by adding an image of the security barrier configuration to the image.

2. The computer system of claim 1, wherein the one or more processors are configured to, individually or collectively, implement a ruleset indicating security barrier configurations for a plurality of sizes, wherein determining the security barrier configuration for closing the location is based on the ruleset.

3. The computer system of claim 1, wherein the one or more processors are configured to, individually or collectively, determine an incursion area for the location based on the second set of user input, wherein determining the security barrier configuration for closing the location is based on the incursion area.

4. The computer system of claim 1, wherein the second set of user input indicates whether the location should allow emergency vehicle access and wherein determining the security barrier configuration for closing the location is based on whether the location should allow emergency vehicle access.

5. The computer system of claim 1, wherein the second set of user input indicates whether the location should allow pedestrian access and wherein determining the security barrier configuration for closing the location is based on whether the location should allow pedestrian access.

6. The computer system of claim 1, wherein the one or more processors are configured to, individually or collectively:
receive a third set of user input indicating a change to the security barrier configuration; and
adjust the image of the security barrier configuration based on the change indicated by the third set of user input.

7. The computer system of claim 1, wherein the one or more processors are configure to, individually or collectively, adjust the map by adding a marker to the map at a position in the image indicating the location.

8. The computer system of claim 1, wherein the one or more processors are configured to, individually or collectively, generate a report comprising (i) the map and (ii) the image of the location with the image of the security barrier configuration.

9. The computer system of claim 1, wherein the one or more processors are configured to, individually or collectively:
determine a plurality of available security barriers; and
determine, based on the plurality of available security barriers, a security barrier missing from the plurality of available security barriers to implement the security barrier configuration.

10. The computer system of claim 1, wherein the one or more processors are configured to, individually or collectively:
receive, from a security barrier, coordinates indicating a location of the security barrier; and
verify that the security barrier is deployed at the location according to the security barrier configuration based on the coordinates.

11. A method comprising:
receiving a first set of user input indicating an address of an event;
retrieving a map showing an area indicated by the address;
receiving a second set of user input indicating a location in the area to be closed for the event;
determining, based on the second set of user input and the map, a size of the location;
determining, based on the size, a security barrier configuration for closing the location; and
adjusting an image of the location by adding an image of the security barrier configuration to the image.

12. The method of claim 11, further comprising implementing a ruleset indicating security barrier configurations for a plurality of sizes, wherein determining the security barrier configuration for closing the location is based on the ruleset.

13. The method of claim 11, further comprising determining an incursion area for the location based on the second set of user input, wherein determining the security barrier configuration for closing the location is based on the incursion area.

14. The method of claim 11, wherein the second set of user input indicates whether the location should allow emergency vehicle access and wherein determining the security barrier configuration for closing the location is based on whether the location should allow emergency vehicle access.

15. The method of claim 11, wherein the second set of user input indicates whether the location should allow pedestrian access and wherein determining the security barrier configuration for closing the location is based on whether the location should allow pedestrian access.

16. The method of claim 11, further comprising:
receiving a third set of user input indicating a change to the security barrier configuration; and
adjusting the image of the security barrier configuration based on the change indicated by the third set of user input.

17. The method of claim 11, further comprising adjusting the map by adding a marker to the map at a position in the image indicating the location.

18. The method of claim 11, further comprising generating a report comprising (i) the map and (ii) the image of the location with the image of the security barrier configuration.

19. The method of claim 11, further comprising:
determining a plurality of available security barriers; and
determining, based on the plurality of available security barriers, a security barrier missing from the plurality of available security barriers to implement the security barrier configuration.

20. A non-transitory computer readable medium storing instructions that, when executed by one or more processors, cause the one or more processors to individually or collectively:
receive a first set of user input indicating an address of an event;
retrieve a map showing an area indicated by the address;
receive a second set of user input indicating a location in the area to be closed for the event;
determine, based on the second set of user input and the map, a size of the location;
determine, based on the size, a security barrier configuration for closing the location; and
adjust an image of the location by adding an image of the security barrier configuration to the image.
